(19) United States
(12) Patent Application Publication
(10) Pub. No.: US 2016/0307641 A1
(43) Pub. Date: Oct. 20, 2016

(54) SHIFT REGISTER, GATE DRIVING CIRCUIT AND DISPLAY DEVICE

(71) Applicant: BOE TECHNOLOGY GROUP CO., LTD., Beijing (CN)

(72) Inventors: Haoliang ZHENG, Beijing (CN); Guangliang SHANG, Beijing (CN)

(21) Appl. No.: 15/085,117

(22) Filed: Mar. 30, 2016

(30) Foreign Application Priority Data
Apr. 14, 2015 (CN) 201510175320.5

(51) Int. Cl. G11C 19/28; G09G 3/36

(52) U.S. Cl. CPC G11C 19/28; G09G 3/3648; G09G 2300/0426; G09G 2310/0248; G09G 2310/08; G09G 2310/0286; G09G 2310/0289

(57) ABSTRACT

The present invention provides a shift register, a gate driving circuit and a display device. The shift register comprises an input unit, an output pull-up unit, a reset unit and an output maintaining unit, the input unit is connected with a signal input terminal, the reset unit and a pull-up control node, and the pull-up control node is a connection node between the input unit and the output pull-up unit; the output pull-up unit is connected with a first signal output terminal, a second signal output terminal, a first clock signal input terminal, the reset unit and the pull-up control node; the reset unit is connected with a reset signal input terminal, a low voltage power supply terminal, the input unit and the output pull-up unit; the output maintaining unit is connected with the first clock signal input terminal, the first signal output terminal and a control signal input terminal.

### FIELD OF THE INVENTION

The present invention relates to the field of display technology, and particularly relates to a shift register, a gate driving circuit and a display device.

### BACKGROUND OF THE INVENTION

A thin film transistor liquid crystal display (TFT-LCD) device displays a frame of picture by sequentially, from top to bottom, enabling each line of pixels by inputting a square wave with a certain width through a gate driving circuit and then outputting required signals for each line of pixels from top to bottom through a source driving circuit.

Currently, most of TFT-LCD devices are provided with a gate driving circuit and a source driving circuit on outer side of a display panel, resulting in a high cost. Thus, in other alternatives, a gate driving circuit composed of multiple stages of shift registers is manufactured on a substrate, that is, a design of gate-drive-on-array (GOA) circuit is employed.

Generally, a gate driving circuit has an output timing including an effective display period and a transition period. FIG. 1 shows a circuit diagram of a shift register of prior art, as shown in FIG. 1, the shift register comprises fourteen transistors M1 to M14. Specifically, when displaying a frame of picture, shift registers from first to N^{th} output one by one to scan gate lines connected thereto, and after every gate lines are scanned, the next frame of picture is to be displayed. Since there is a transition period between display of any two adjacent frames of picture, and during the transition period, each of the shift registers does not operate, output potentials of the shift registers become zero simultaneously in the transition period (since output potentials of the shift registers are negative during scanning, a pull-up procedure is performed in the transition period), resulting in unstable output of the shift registers. Particularly, when two frames of picture to be displayed have different refresh frequencies, the transition period between them is long, which results in not only a poor stability of output of the gate driving circuit but also a large power consumption thereof.

### SUMMARY OF THE INVENTION

An object of the present invention is, in view of above problems existing in the shift register of prior art, to provide a shifter register, a gate driving circuit comprising the shift register and a display device comprising the gate driving circuit, which have a lower power consumption.

In order to achieve above object, a technical solution of the present invention is a shift register, comprising an input unit, an output pull-up unit, a reset unit and an output maintaining unit, wherein the input unit is connected with a signal input terminal, the reset unit and a pull-up control node, and is configured to control potential of the pull-up control node in accordance with a signal inputted from the signal input terminal, the pull-up control node is a connection node between the input unit and the output pull-up unit; the output pull-up unit is connected with a first signal output terminal, a second signal output terminal, a first clock signal input terminal, the reset unit and the pull-up control node, and is configured to control output of the first signal output terminal in accordance with potential of the pull-up control node and signal inputted from the first clock signal input terminal; the reset unit is connected with a reset signal input terminal, a low voltage power supply terminal, the input unit and the output pull-up unit, and is configured to reset signals outputted by the input unit and the output pull-up unit in accordance with signal inputted from the reset signal input terminal; the output maintaining unit is connected with the first clock signal input terminal, the first signal output terminal and a control signal input terminal, and is configured to maintain output of the first signal output terminal in accordance with signals inputted from the control signal input terminal and the first clock signal input terminal.

Preferably, the shift register further comprises a pull-down control unit and a pull-down unit, wherein the pull-down control unit is connected with a second clock signal input terminal and a pull-down node, and is configured to control potential of the pull-down node in accordance with signal inputted from the second clock signal input terminal, the pull-down node is a connection node between the pull-down control unit and the pull-down unit; the pull-down unit is connected with the signal input terminal, the first clock signal input terminal, the pull-down node, the pull-up control node and the low voltage power supply terminal, and is configured to pull down potential of the pull-down node in accordance with potential of the pull-up control node, signal inputted from the signal input terminal and signal inputted from the first clock signal input terminal.

Further preferably, the pull-down control unit comprises a fifth transistor, the pull-down unit comprises a sixth transistor, a seventh transistor and a ninth transistor, a first electrode of the fifth transistor is connected with the second clock signal input terminal, a second electrode of the fifth transistor is connected with the pull-down node, and a control electrode of the fifth transistor is also connected with the second clock signal input terminal; a first electrode of the sixth transistor is connected with the pull-down node, a second electrode of the sixth transistor is connected the low voltage power supply terminal, and a control electrode of the sixth transistor is connected with the pull-up control node; a first electrode of the seventh transistor is connected with the pull-down node, a second electrode of the seventh transistor is connected with the low voltage power supply terminal, and a control electrode of the seventh transistor is connected with the signal input terminal; a first electrode of the ninth transistor is connected with the pull-down node, a second electrode of the ninth transistor is connected with the low voltage power supply terminal, and a control electrode of the ninth transistor is connected with the first clock signal input terminal.

Preferably, the input unit comprises a first transistor, a first electrode of the first transistor is connected with the signal input terminal, a second electrode of the first transistor is connected with the pull-up control node, and a control electrode of the first transistor is also connected with the signal input terminal.

Preferably, the output pull-up unit comprises a third transistor, an eleventh transistor and a storage capacitor, a first electrode of the third transistor is connected with the first clock signal input terminal, a second electrode of the third transistor is connected with the first signal output terminal, and a control electrode of the third transistor is connected with the pull-up control node; a first electrode of the eleventh transistor is connected with the first clock signal input terminal, a second electrode of the eleventh transistor is connected with the second signal output terminal, and a control electrode of the eleventh transistor is connected with the pull-up control node; a first terminal of the storage capacitor is connected with the pull-up control node, and a second terminal of the storage capacitor is connected with the first signal output terminal.

Further preferably, the output maintaining unit comprises a fifteenth transistor, a first electrode of the fifteenth transistor is connected with the first clock signal input terminal, a second electrode of the fifteenth transistor is connected with the first signal output terminal, and a control electrode of the fifteenth transistor is connected with the control signal input terminal.

Further preferably, the output maintaining unit further comprises a sixteenth transistor, a first electrode of the sixteen transistor is connected with the first clock signal input terminal, a second electrode of the sixteenth transistor is connected with the pull-up control node, and a control electrode of the sixteenth transistor is connected with the control signal input terminal.

Further preferably, the output maintaining unit further comprises a seventeenth transistor, a first electrode of the seventeenth transistor is connected with the first clock signal input terminal, a second electrode of the seventeenth transistor is connected with the pull-down node, and a control electrode of the seventeenth transistor is connected with the control signal input terminal.

Preferably, the reset unit comprises an input reset module and an output reset module, the input reset module is connected with the reset signal input terminal, the low voltage power supply terminal and the input unit, and is configured to reset signal outputted by the input unit in accordance with signal inputted from the reset signal input terminal; the output reset module is connected with the reset signal input terminal, the low voltage power supply terminal and the first signal output terminal, and is configured to reset signal outputted from the first signal output terminal in accordance with signal inputted from the reset signal input terminal.

Further preferably, the input reset module comprises a second transistor, the output reset module comprises a fourth transistor, a first electrode of the second transistor is connected with the pull-up control node, a second electrode of the second transistor is connected with the low voltage power supply terminal, and a control electrode of the second transistor is connected with the reset signal input terminal; a first electrode of the fourth transistor is connected with the first signal output terminal, a second electrode of the fourth transistor is connected with the low voltage power supply terminal, and a control electrode of the fourth transistor is connected with the reset signal input terminal.

Further preferably, the shift register further comprises an input noise reducing unit, the input noise reducing unit is connected with the pull-down node, the pull-up control node and the low voltage power supply terminal, and is configured to reduce output noise at the pull-up control node in accordance with potential of the pull-down node.

Further preferably, the input noise reducing unit comprises an eighth transistor, a first electrode of the eighth transistor is connected with the pull-up control node, a second electrode of the eighth transistor is connected with the low voltage power supply terminal, and a control electrode of the eighth transistor is connected with the pull-down node.

Further preferably, the shift register further comprises an output noise reducing unit, the output noise reducing unit is connected with the pull-down node, the second clock signal input terminal, the low voltage power supply terminal, the first signal output terminal and the second signal output terminal, and is configured to reduce output noise at the first signal output terminal in accordance with potential of the pull-down control node and signal inputted from the second clock signal input terminal.

Further preferably, the output noise reducing unit comprises a twelfth transistor, a thirteenth transistor and a fourteenth transistor, a first electrode of the twelfth transistor is connected with the second signal output terminal, a second electrode of the twelfth transistor is connected with the low voltage power supply terminal, and a control electrode of the twelfth transistor is connected with the pull-down node; a first electrode of the thirteenth transistor is connected with the first signal output terminal, a second electrode of the thirteenth transistor is connected with the low voltage power supply terminal, and a control electrode of the thirteenth transistor is connected with the pull-down node; a first electrode of the fourteenth transistor is connected with the first signal output terminal, a second electrode of the fourteenth transistor is connected with the low voltage power supply terminal, and a control electrode of the fourteenth transistor is connected with the second clock signal input terminal.

Further preferably, the shift register further comprises a discharging unit, the discharging unit is connected with a frame gating signal input terminal and the pull-down node, and is configured to discharge the pull-up control node, the first signal output terminal and the second signal output terminal in accordance with signal inputted from the frame gating signal input terminal during a period after finish of display of a frame and before start of display of the next frame.

Further preferably, the discharging unit comprises a tenth transistor, a first electrode of the tenth transistor is connected with the frame gating signal input terminal, a second electrode of the tenth transistor is connected with the pull-down node, and a control electrode of the tenth transistor is also connected with the frame gating signal input terminal.

In order to achieve above object, a technical solution of the present invention is a gate driving circuit, which comprises any of above shift registers.

In order to achieve above object, a technical solution of the present invention is a display device, which comprises the gate driving circuit as above.

The present invention has following beneficial effects.

In the shift register of the present invention, the output maintaining unit is provided for maintaining stability of output from the first signal input terminal in accordance with signals inputted from the control signal input terminal and the first clock signal input terminal connected thereto, so that when two adjacent frames of picture to be displayed have different refresh frequencies, poor stability of output from the gate driving circuit due to a long transition period between the two adjacent frames is avoided, and the power consumption is also reduced.

Since the gate driving circuit of the present invention comprises the above shift register, the output of the gate driving circuit is stable and the power consumption thereof is low.

Since the display device of the present invention comprises the above gate driving circuit, it has the same advantages as above.

### BRIEF DESCRIPTION OF THE DRAWINGS

FIG. 1 shows a circuit diagram of a shift register of prior art;

FIG. 2 shows a structural diagram of a shift register in accordance with a first embodiment of the present invention;

FIG. 3 shows another structural diagram of a shift register in accordance with the first embodiment of the present invention;

FIG. 4 shows a circuit diagram of a shift register in accordance with the first embodiment of the present invention;

FIG. 5 shows an operation timing of the circuit in FIG. 4;

FIG. 6 shows another circuit diagram of a shift register in accordance with the first embodiment of the present invention;

FIG. 7 shows still another circuit diagram of a shift register in accordance with the first embodiment of the present invention.

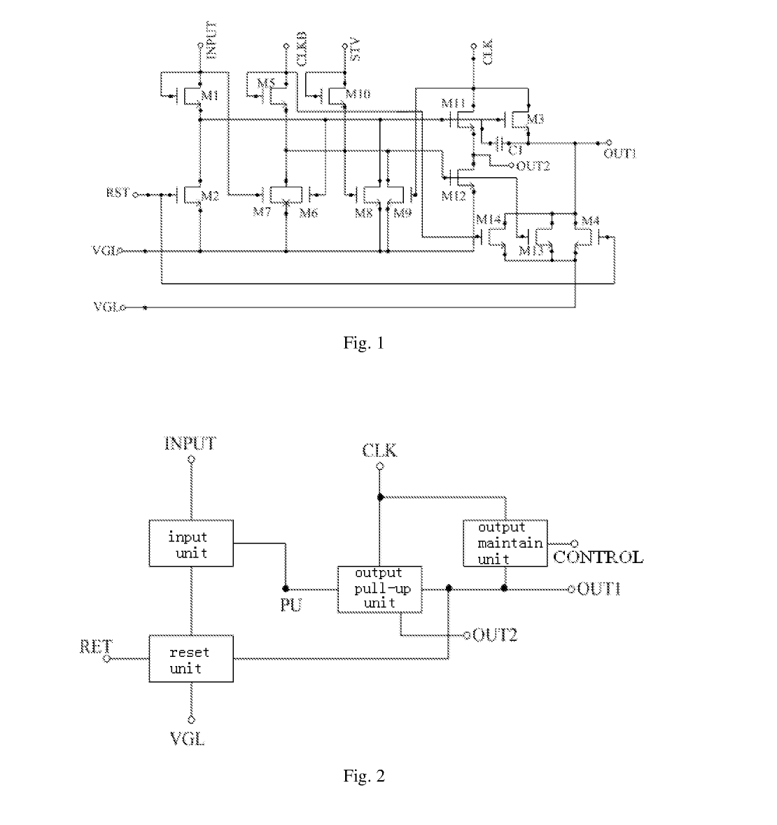

### DETAILED DESCRIPTION OF THE EMBODIMENTS

To make those skilled in the art understand the technical solutions of the present invention better, the present invention will be further described in detail below in conjunction with accompanying drawings and specific implementations.

Transistors employed in embodiments of the present invention may be thin film transistors, field effect transistors or other devices with the same properties. Since a source and a drain of a transistor are symmetric to each other, there is no difference between the source and the drain. In embodiments of the present invention, to distinguish the source and the drain of the transistor, one electrode of the transistor is referred to as a first electrode, another electrode of the transistor is referred to as a second electrode, and a gate of the transistor is referred to as a control electrode. In addition, transistors are divided into N-type and P-type in accordance with characteristics thereof. Following embodiments are described by taking N-type transistors as example, when N-type transistors are adopted, the first electrode of the transistor is the source, the second electrode of the transistor is the drain, and when high level is inputted from the gate, the source and the drain are connected with each other. For P-type transistors, conditions are reverse. It is conceivable that, realization with P-type transistors can be easily obtained by persons skilled in the art without any creative effort, thus falls within the protection scope of embodiments of the present invention.

### First Embodiment

As shown in FIG. 2, the present embodiment provides a shift register, comprising an input unit, an output pull-up unit, a reset unit and an output maintaining unit, wherein, the input unit is connected with a signal input terminal INPUT, the reset unit and a pull-up control node PU, and is configured to control potential of the pull-up control node PU in accordance with signal inputted from the signal input terminal INPUT; the pull-up control node PU is a connection node between the input unit and the output pull-up unit; the output pull-up unit is connected with a first signal output terminal OUT1, a second signal output terminal OUT2, a first clock signal input terminal CLK, the reset unit and the pull-up control node PU, and is configured to control output of the first signal output terminal OUT1 in accordance with potential of the pull-up control node PU and signal inputted from the first clock signal input terminal CLK; the reset unit is connected with a reset signal input terminal RET, a low voltage power supply terminal VGL, the input unit and the output pull-up unit, and is configured to reset signals outputted by the input unit and the output pull-up unit in accordance with signal inputted from the reset signal input terminal RET; the output maintaining unit is connected with the first clock signal input terminal CLK, the first signal output terminal OUT1 and a control signal input terminal CONTROL, and is configured to maintain output of the first signal output terminal OUT1 in accordance with signals inputted from the control signal input terminal CONTROL and the first clock signal input terminal CLK.

It should be noted that, the signal outputted from the first signal output terminal OUT1 is provided to the gate line corresponding to the present shift register, the signal outputted from the second signal output terminal OUT2 is provided to the reset signal input terminal RET of the previous shift register and the signal input terminal INPUT of the next shift register.

In the shift register of the present embodiment, the output maintaining unit is provided for maintaining stability of output from the first signal input terminal OUT1 in accordance with signals inputted from the control signal input terminal CONTROL and the first clock signal input terminal CLK connected thereto, so that when two adjacent frames of picture to be displayed have different refresh frequencies, poor stability of output from the gate driving circuit due to a long transition period between the two adjacent frames is avoided, and the power consumption is also reduced.

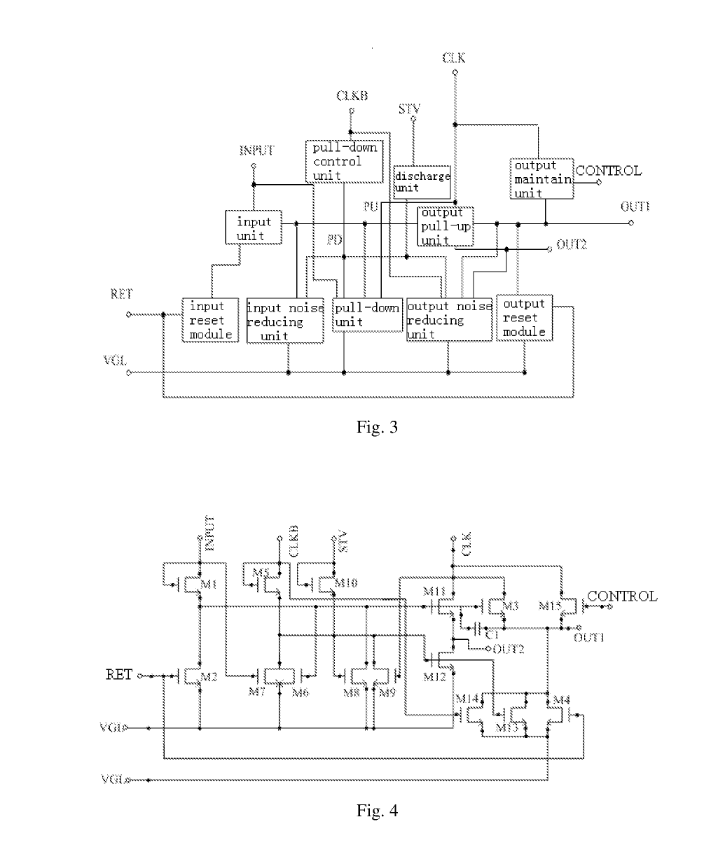

As shown in FIG. 3, as a preferred implementation of the present embodiment, the shift register not only comprises the input unit, the output pull-up unit, the reset unit and the output maintaining unit, but also preferably comprises a pull-down control unit and a pull-down unit, the pull-down control unit is connected with a second clock signal input terminal CLKB and a pull-down node PD, and is configured to control potential of the pull-down node PD in accordance with signal inputted from the second clock signal input terminal CLKB, the pull-down node PD is a connection node between the pull-down control unit and the pull-down unit; the pull-down unit is connected with the signal input terminal INPUT, the first clock signal input terminal CLK, the pull-down node PD, the pull-up control node PU and the low voltage power supply terminal VGL, and is configured to pull down potential of the pull-down node PD in accordance with potential of the pull-up control node PU, signal inputted from the signal input terminal INPUT and signal inputted from the first clock signal input terminal CLK.

Further preferably, the reset unit comprises an input reset module and an output reset module, the input reset module is connected with the reset signal input terminal RET, the low voltage power supply terminal VGL and the input unit, and is configured to reset signal outputted by the input unit in accordance with signal inputted from the reset signal input terminal RET; the output reset module is connected with the reset signal input terminal RET, the low voltage power supply terminal VGL and the first signal output terminal OUT1, and is configured to reset signal outputted from the first signal output terminal OUT1 in accordance with signal inputted from the reset signal input terminal RET.

Further preferably, the shift register further comprises an input noise reducing unit, the input noise reducing unit is connected with the pull-down node PD, the pull-up control node PU and the low voltage power supply terminal VGL, and is configured to reduce output noise at the pull-up control node PU in accordance with potential of the pull-down node PD.

Further preferably, the shift register further comprises an output noise reducing unit, the output noise reducing unit is connected with the pull-down node PD, the second clock signal input terminal CLKB, the low voltage power supply terminal VGL, the first signal output terminal OUT1 and the second signal output terminal OUT2, and is configured to reduce output noise at the first signal output terminal OUT1 in accordance with potential of the pull-down control node PD and signal inputted from the second clock signal input terminal CLKB.

Further preferably, the shift register further comprises a discharging unit, the discharging unit is connected with a frame gating signal input terminal STV and the pull-down node PD, and is configured to discharge the pull-up control node PU, the first signal output terminal OUT1 and the second signal output terminal OUT2 in accordance with signal inputted from the frame gating signal input terminal STV during a period after finish of display of a frame and before start of display of the next frame.

As shown in FIG. 4, as a specific preferred implementation of the present embodiment, the input unit comprises a first transistor M1, a first electrode of the first transistor M1 is connected with the signal input terminal INPUT, a second electrode of the first transistor M1 is connected with the pull-up control node PU, and a control electrode of the first transistor M1 is also connected with the signal input terminal INPUT. The output pull-up unit comprises a third transistor M3, an eleventh transistor M11 and a storage capacitor C1, a first electrode of the third transistor M3 is connected with the first clock signal input terminal CLK, a second electrode of the third transistor M3 is connected with the first signal output terminal OUT1, and a control electrode of the third transistor M3 is connected with the pull-up control node PU; a first electrode of the eleventh transistor M11 is connected with the first clock signal input terminal CLK, a second electrode of the eleventh transistor M11 is connected with the second signal output terminal OUT2, and a control electrode of the eleventh transistor M11 is connected with the pull-up control node PU; a first terminal of the storage capacitor C1 is connected with the pull-up control node PU, and a second terminal of the storage capacitor C1 is connected with the first signal output terminal OUT1. The output maintaining unit comprises a fifteenth transistor M15, a first electrode of the fifteenth transistor M15 is connected with the first clock signal input terminal CLK, a second electrode of the fifteenth transistor M15 is connected with the first signal output terminal OUT1, and a control electrode of the fifteenth transistor M15 is connected with the control signal input terminal CONTROL. The input reset module comprises a second transistor M2, the output reset module comprises a fourth transistor M4, a first electrode of the second transistor M2 is connected with the pull-up control node PU, a second electrode of the second transistor M2 is connected with the low voltage power supply terminal VGL, and a control electrode of the second transistor M2 is connected with the reset signal input terminal RET; a first electrode of the fourth transistor M4 is connected with the first signal output terminal OUT1, a second electrode of the fourth transistor M4 is connected with the low voltage power supply terminal VGL, and a control electrode of the fourth transistor M4 is connected with the reset signal input terminal RET. The pull-down control unit comprises a fifth transistor M5, the pull-down unit comprises a sixth transistor M6, a seventh transistor M7 and a ninth transistor M9, a first electrode of the fifth transistor M5 is connected with the second clock signal input terminal CLKB, a second electrode of the fifth transistor M5 is connected with the pull-down node PD, and a control electrode of the fifth transistor M5 is also connected with the second clock signal input terminal CLKB; a first electrode of the sixth transistor M6 is connected with the pull-down node PD, a second electrode of the sixth transistor M6 is connected the low voltage power supply terminal VGL, and a control electrode of the sixth transistor M6 is connected with the pull-up control node PU; a first electrode of the seventh transistor M7 is connected with the pull-down node PD, a second electrode of the seventh transistor M7 is connected with the low voltage power supply terminal VGL, and a control electrode of the seventh transistor M7 is connected with the signal input terminal INPUT; a first electrode of the ninth transistor M9 is connected with the pull-down node PD, a second electrode of the ninth transistor M9 is connected with the low voltage power supply terminal VGL, and a control electrode of the ninth transistor M9 is connected with the first clock signal input terminal CLK. The input noise reducing unit comprises an eighth transistor M8, a first electrode of the eighth transistor M8 is connected with the pull-up control node PU, a second electrode of the eighth transistor M8 is connected with the low voltage power supply terminal VGL, and a control electrode of the eighth transistor M8 is connected with the pull-down node PD. The output noise reducing unit comprises a twelfth transistor M12, a thirteenth transistor M13 and a fourteenth transistor M14, a first electrode of the twelfth transistor M12 is connected with the second signal output terminal OUT2, a second electrode of the twelfth transistor M12 is connected with the low voltage power supply terminal VGL, and a control electrode of the twelfth transistor M12 is connected with the pull-down node PD; a first electrode of the thirteenth transistor M13 is connected with the first signal output terminal OUT1, a second electrode of the thirteenth transistor M13 is connected with the low voltage power supply terminal VGL, and a control electrode of the thirteenth transistor M13 is connected with the pull-down node PD; a first electrode of the fourteenth transistor M14 is connected with the first signal output terminal OUT1, a second electrode of the fourteenth transistor M14 is connected with the low voltage power supply terminal VGL, and a control electrode of the fourteenth transistor is connected with the second clock signal input terminal CLKB. The discharging unit comprises a tenth transistor M10, a first electrode of the tenth transistor M10 is connected with the frame gating signal input terminal STV, a second electrode of the tenth transistor M10 is connected with the pull-down node PD, and a control electrode of the tenth transistor M10 is also connected with the frame gating signal input terminal STV.

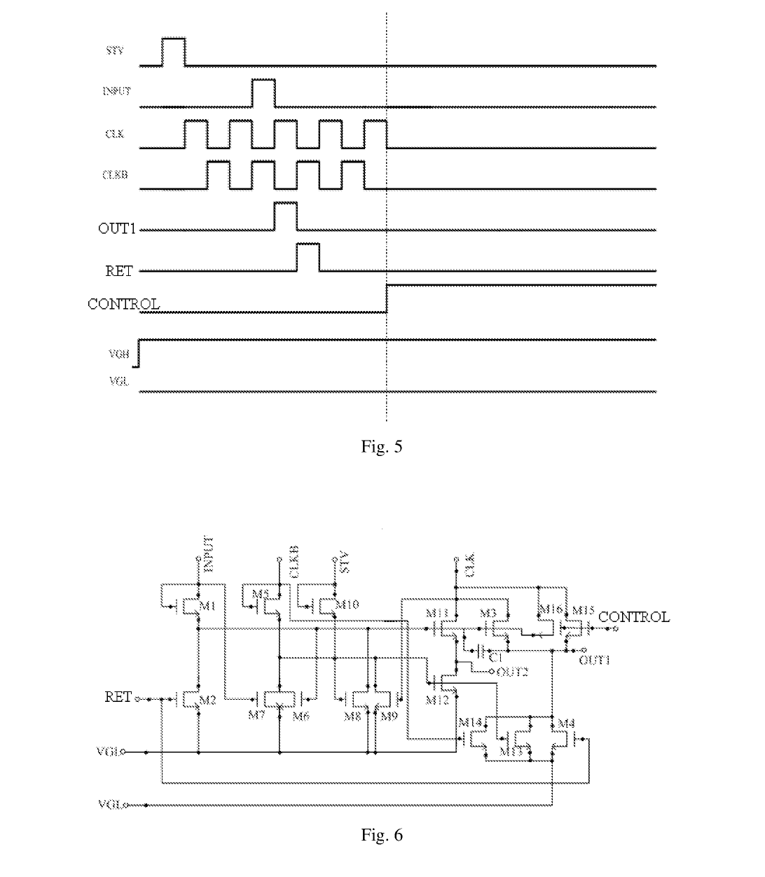

The shift register in FIG. 4 is described below in conjunction with the timing diagram shown in FIG. 5.

In an initialization phase, a high level signal is first inputted from the frame gating signal input terminal STV, at this time, the tenth transistor M10 is turned on, potential of the pull-down node PD is pulled up to be the high level, thus the eighth transistor M8, the twelfth transistor M12 and the thirteenth transistor M13, the control electrodes of which are connected with the pull-down node PD, are turned on, residual charges on the pull-up control node PU, the second signal output terminal OUT2 and the first signal output terminal OUT1 are discharged; then a low level signal is inputted from the frame gating signal input terminal STV, and a high level signal is inputted from the signal input terminal INPUT, the first transistor M1 is turned on, the pull-up control node PU is charged, and the seventh transistor M7 is turned on, thus potential of the pull-down node PD is pulled down, the eighth transistor M8 is prevented from being turned on to pull down potential of the pull-up control node PU.

In a pull-up output phase, a high level signal is inputted from the first clock signal input terminal CLK, since the pull-up control node PU is charged in the previous phase, at this time, the pull-up control node PU is at a high level, the third transistor M3 and the eleventh transistor M11 are turned on, the first signal output terminal OUT1 outputs a high level signal, at the same time, the ninth transistor M9 is also turned on, the pull-down node PD is maintained at a low level, the eighth transistor M8 is prevented from being turned on to pull down potential of the pull-up control node PU and further affect output of the first signal output terminal OUT1.

In a reset phase, the signal inputted from the first clock signal input terminal CLK is changed from high level to low level, and signals inputted from the second clock signal input terminal CLKB and the reset signal input terminal RET are at a high level, at this time, the fifth transistor M5 is turned on, the pull-down node PD is pulled up to a high level, at the same time, the second transistor M2 and the fourth transistor M4 are turned on, potential of the pull-up control node PU is pulled down to be a low level, and potential outputted from the first signal output terminal OUT1 is also pulled down to be a low level, that is, the pull-up control node PU and the first signal output terminal OUT1 are reset. At this time, the eighth transistor M8, the twelfth transistor M12, the thirteenth transistor M13 and the fourteenth transistor M14 are turned on to reduce noise outputted from the pull-up control node PU and the first signal output terminal OUT1, so as to avoid error output.

In an output maintaining phase, a low level signal is inputted from the first clock signal input terminal CLK, a high level signal is inputted from the control signal input terminal CONTROL, the fifteenth transistor M15 is turned on so that the first signal output terminal OUT1 is maintained to output a low level until arrival of the next frame. At this time, not only the power consumption is reduced, but also influence of leakage and external noise on the signal outputted from the first signal output terminal OUT1 is reduced.

FIG. 6 shows another implementation of the present embodiment, which is similar to above shift register, the difference is in that, the output maintaining unit of the shift register comprises a fifteenth transistor M15 and a sixteenth transistor M16, a first electrode of the fifteenth transistor M15 is connected with the first clock signal input terminal CLK, a second electrode of the fifteenth transistor M15 is connected with the first signal output terminal OUT1, and a control electrode of the fifteenth transistor M15 is connected with the control signal input terminal CONTROL; a first electrode of the sixteen transistor M16 is connected with the first clock signal input terminal CLK, a second electrode of the sixteenth transistor M16 is connected with the pull-up control node PU, and a control electrode of the sixteenth transistor M16 is connected with the control signal input terminal CONTROL.

The operation procedure of the shift register is similar to that of the above shift register, the difference is in that, in the output maintaining phase, a low level signal is inputted from the first clock signal input terminal CLK, a high level signal is inputted from the control signal input terminal CONTROL, the fifteenth transistor M15 is turned on so that the first signal output terminal OUT1 is maintained to output a low level, and the sixteenth transistor M16 is turned on, at this time, the pull-up control node PU is maintained at a low level to avoid influence on signal outputted from the first signal output terminal OUT1, until arrival of the next frame. At this time, not only the power consumption is reduced, but also influence of leakage and external noise on the signal outputted from the first signal output terminal OUT1 is reduced.

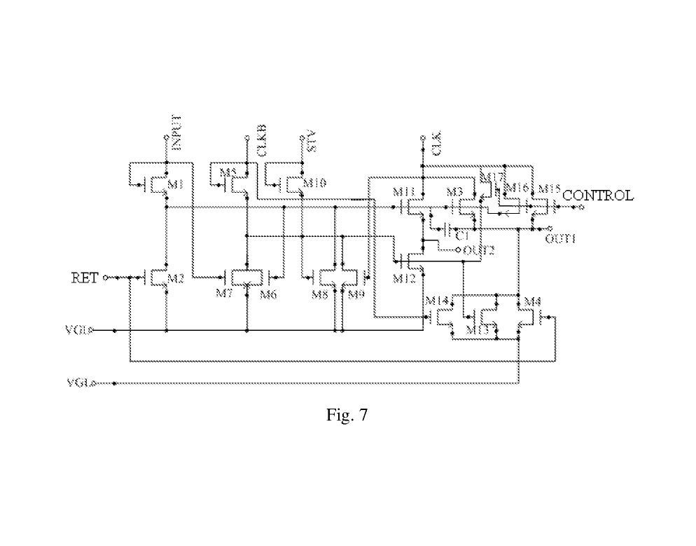

FIG. 7 shows still another implementation of the present embodiment, which is similar to above shift registers, the difference is in that, the output maintaining unit of the shift register comprises a fifteenth transistor M15, a sixteenth transistor M16 and a seventeenth transistor M17, a first electrode of the fifteenth transistor M15 is connected with the first clock signal input terminal CLK, a second electrode of the fifteenth transistor M15 is connected with the first signal output terminal OUT1, and a control electrode of the fifteenth transistor M15 is connected with the control signal input terminal CONTROL; a first electrode of the sixteen transistor M16 is connected with the first clock signal input terminal CLK, a second electrode of the sixteenth transistor M16 is connected with the pull-up control node PU, and a control electrode of the sixteenth transistor M16 is connected with the control signal input terminal CONTROL; a first electrode of the seventeenth transistor M17 is connected with the first clock signal input terminal CLK, a second electrode of the seventeenth transistor M17 is connected with the pull-down node PD, and a control electrode of the seventeenth transistor M17 is connected with the control signal input terminal CONTROL.

The operation procedure of the shift register is similar to that of the above shift registers, the difference is in that, in the output maintaining phase, a low level signal is inputted from the first clock signal input terminal CLK, a high level signal is inputted from the control signal input terminal CONTROL, the fifteenth transistor M15 is turned on so that the first signal output terminal OUT1 is maintained to output a low level, the sixteenth transistor M16 is turned on, at this time, the pull-up control node PU is maintained at a low level to avoid influence on signal outputted from the first signal output terminal OUT1, and the seventeenth transistor M17 is turned on, the pull-down node PD is at a low level to avoid influence on signal outputted from the first signal output terminal OUT1, until arrival of the next frame. At this time, not only the power consumption is reduced, but also influence of leakage and external noise on the signal outputted from the first signal output terminal OUT1 is reduced.

Correspondingly, the present embodiment provides a gate driving circuit comprising a plurality of cascaded shift registers which are any of above shift registers, wherein the second signal output terminal OUT2 of each stage of shift register is connected with the reset signal input terminal RET of the previous stage of shift register and the signal input terminal INPUT of the next stage of shift register.

Correspondingly, the present embodiment also provides a display device comprising the above gate driving circuit. The display device may be a mobile phone, a tablet computer, a television, a display, a notebook computer, a digital photo frame, a navigator, or any product or member with display function.

Of course, the display device of the present embodiment may further comprise other conventional structures, such as display driving unit, etc.

It may be understood that the above implementations are merely exemplary implementations adopted for describing the principle of the present invention, but the present invention is not limited thereto. For a person of ordinary skill in the art, various variations and improvements may be made without departing from the spirit and essence of the present invention, and those variations and improvements should also be regarded as falling into the protection scope of the present invention.

1. A shift register, comprising an input unit, an output pull-up unit, a reset unit and an output maintaining unit, wherein,
the input unit is connected with a signal input terminal, the reset unit and a pull-up control node, and is configured to control potential of the pull-up control node in accordance with a signal inputted from the signal input terminal, the pull-up control node is a connection node between the input unit and the output pull-up unit;
the output pull-up unit is connected with a first signal output terminal, a second signal output terminal, a first clock signal input terminal, the reset unit and the pull-up control node, and is configured to control output of the first signal output terminal in accordance with potential of the pull-up control node and signal inputted from the first clock signal input terminal;
the reset unit is connected with a reset signal input terminal, a low voltage power supply terminal, the input unit and the output pull-up unit, and is configured to reset signals outputted by the input unit and the output pull-up unit in accordance with signal inputted from the reset signal input terminal;
the output maintaining unit is connected with the first clock signal input terminal, the first signal output terminal and a control signal input terminal, and is configured to maintain output of the first signal output terminal in accordance with signals inputted from the control signal input terminal and the first clock signal input terminal.

2. The shift register of claim 1, further comprises a pull-down control unit and a pull-down unit,
the pull-down control unit is connected with a second clock signal input terminal and a pull-down node, and is configured to control potential of the pull-down node in accordance with signal inputted from the second clock signal input terminal, the pull-down node is a connection node between the pull-down control unit and the pull-down unit;
the pull-down unit is connected with the signal input terminal, the first clock signal input terminal, the pull-down node, the pull-up control node and the low voltage power supply terminal, and is configured to pull down potential of the pull-down node in accordance with potential of the pull-up control node, signal inputted from the signal input terminal and signal inputted from the first clock signal input terminal.

3. The shift register of claim 2, wherein the pull-down control unit comprises a fifth transistor, the pull-down unit comprises a sixth transistor, a seventh transistor and a ninth transistor,
a first electrode of the fifth transistor is connected with the second clock signal input terminal, a second electrode of the fifth transistor is connected with the pull-down node, and a control electrode of the fifth transistor is also connected with the second clock signal input terminal;
a first electrode of the sixth transistor is connected with the pull-down node, a second electrode of the sixth transistor is connected the low voltage power supply terminal, and a control electrode of the sixth transistor is connected with the pull-up control node;
a first electrode of the seventh transistor is connected with the pull-down node, a second electrode of the seventh transistor is connected with the low voltage power supply terminal, and a control electrode of the seventh transistor is connected with the signal input terminal;
a first electrode of the ninth transistor is connected with the pull-down node, a second electrode of the ninth transistor is connected with the low voltage power supply terminal, and a control electrode of the ninth transistor is connected with the first clock signal input terminal.

4. The shift register of claim 1, wherein the input unit comprises a first transistor,
a first electrode of the first transistor is connected with the signal input terminal, a second electrode of the first transistor is connected with the pull-up control node, and a control electrode of the first transistor is also connected with the signal input terminal.

5. The shift register of claim 2, wherein the input unit comprises a first transistor,
a first electrode of the first transistor is connected with the signal input terminal, a second electrode of the first transistor is connected with the pull-up control node, and a control electrode of the first transistor is also connected with the signal input terminal.

6. The shift register of claim 1, wherein the output pull-up unit comprises a third transistor, an eleventh transistor and a storage capacitor,
a first electrode of the third transistor is connected with the first clock signal input terminal, a second electrode of the third transistor is connected with the first signal output terminal, and a control electrode of the third transistor is connected with the pull-up control node;
a first electrode of the eleventh transistor is connected with the first clock signal input terminal, a second electrode of the eleventh transistor is connected with the second signal output terminal, and a control electrode of the eleventh transistor is connected with the pull-up control node;
a first terminal of the storage capacitor is connected with the pull-up control node, and a second terminal of the storage capacitor is connected with the first signal output terminal.

7. The shift register of claim 2, wherein the output pull-up unit comprises a third transistor, an eleventh transistor and a storage capacitor,
a first electrode of the third transistor is connected with the first clock signal input terminal, a second electrode of the third transistor is connected with the first signal output terminal, and a control electrode of the third transistor is connected with the pull-up control node;
a first electrode of the eleventh transistor is connected with the first clock signal input terminal, a second electrode of the eleventh transistor is connected with the second signal output terminal, and a control electrode of the eleventh transistor is connected with the pull-up control node;
a first terminal of the storage capacitor is connected with the pull-up control node, and a second terminal of the storage capacitor is connected with the first signal output terminal.

8. The shift register of claim 2, wherein the output maintaining unit comprises a fifteenth transistor,
a first electrode of the fifteenth transistor is connected with the first clock signal input terminal, a second electrode of the fifteenth transistor is connected with the first signal output terminal, and a control electrode of the fifteenth transistor is connected with the control signal input terminal.

9. The shift register of claim 8, wherein the output maintaining unit further comprises a sixteenth transistor,
a first electrode of the sixteen transistor is connected with the first clock signal input terminal, a second electrode of the sixteenth transistor is connected with the pull-up control node, and a control electrode of the sixteenth transistor is connected with the control signal input terminal.

10. The shift register of claim 9, wherein the output maintaining unit further comprises a seventeenth transistor,
a first electrode of the seventeenth transistor is connected with the first clock signal input terminal, a second electrode of the seventeenth transistor is connected with the pull-down node, and a control electrode of the seventeenth transistor is connected with the control signal input terminal.

11. The shift register of claim 1, wherein the reset unit comprises an input reset module and an output reset module,
the input reset module is connected with the reset signal input terminal, the low voltage power supply terminal and the input unit, and is configured to reset signal outputted by the input unit in accordance with signal inputted from the reset signal input terminal;
the output reset module is connected with the reset signal input terminal, the low voltage power supply terminal and the first signal output terminal, and is configured to reset signal outputted from the first signal output terminal in accordance with signal inputted from the reset signal input terminal.

12. The shift register of claim 11, wherein the input reset module comprises a second transistor, the output reset module comprises a fourth transistor,
a first electrode of the second transistor is connected with the pull-up control node, a second electrode of the second transistor is connected with the low voltage power supply terminal, and a control electrode of the second transistor is connected with the reset signal input terminal;
a first electrode of the fourth transistor is connected with the first signal output terminal, a second electrode of the fourth transistor is connected with the low voltage power supply terminal, and a control electrode of the fourth transistor is connected with the reset signal input terminal.

13. The shift register of claim 2, further comprises an input noise reducing unit,
the input noise reducing unit is connected with the pull-down node, the pull-up control node and the low voltage power supply terminal, and is configured to reduce output noise at the pull-up control node in accordance with potential of the pull-down node.

14. The shift register of claim 13, wherein the input noise reducing unit comprises an eighth transistor,
a first electrode of the eighth transistor is connected with the pull-up control node, a second electrode of the eighth transistor is connected with the low voltage power supply terminal, and a control electrode of the eighth transistor is connected with the pull-down node.

15. The shift register of claim 2, further comprises an output noise reducing unit,
the output noise reducing unit is connected with the pull-down node, the second clock signal input terminal, the low voltage power supply terminal, the first signal output terminal and the second signal output terminal, and is configured to reduce output noise at the first signal output terminal in accordance with potential of the pull-down control node and signal inputted from the second clock signal input terminal.

16. The shift register of claim 15, wherein the output noise reducing unit comprises a twelfth transistor, a thirteenth transistor and a fourteenth transistor,
a first electrode of the twelfth transistor is connected with the second signal output terminal, a second electrode of the twelfth transistor is connected with the low voltage power supply terminal, and a control electrode of the twelfth transistor is connected with the pull-down node;
a first electrode of the thirteenth transistor is connected with the first signal output terminal, a second electrode of the thirteenth transistor is connected with the low voltage power supply terminal, and a control electrode of the thirteenth transistor is connected with the pull-down node;
a first electrode of the fourteenth transistor is connected with the first signal output terminal, a second electrode of the fourteenth transistor is connected with the low voltage power supply terminal, and a control electrode of the fourteenth transistor is connected with the second clock signal input terminal.

17. The shift register of claim 2, further comprises a discharging unit,
the discharging unit is connected with a frame gating signal input terminal and the pull-down node, and is configured to discharge the pull-up control node, the first signal output terminal and the second signal output terminal in accordance with signal inputted from the frame gating signal input terminal during a period after finish of display of a frame and before start of display of the next frame.

18. The shift register of claim 17, wherein the discharging unit comprises a tenth transistor,
a first electrode of the tenth transistor is connected with the frame gating signal input terminal, a second electrode of the tenth transistor is connected with the pull-down node, and a control electrode of the tenth transistor is also connected with the frame gating signal input terminal.

19. A gate driving circuit, comprising a plurality of cascaded shift registers of claim 1, wherein,
the second signal input terminal of each stage of shift register is connected with the reset signal input terminal of the previous stage of shift register and the signal input terminal of the next stage of shift register.

20. A display device, comprising the gate driving circuit of claim 19.
